(19) United States
(12) Patent Application Publication
(10) Pub. No.: US 2005/0213408 A1
(43) Pub. Date: Sep. 29, 2005

(54) Ripple refresh circuit and method for sequentially refreshing a semiconductor memory system

(75) Inventor: Hau-Tai Shieh, Hsinchu City (TW)

Correspondence Address: DUANE MORRIS LLP;IP DEPARTMENT (TSMC), 4200 ONE LIBERTY PLACE, PHILADELPHIA, PA, 19103-7396, US

(73) Assignee: Taiwan Semiconductor Manufacturing Company, Ltd.

(21) Appl. No.: 10/812,253

(22) Filed: Mar. 29, 2004

(51) Int. Cl. G11C 11/406

(52) U.S. Cl. 365/222; 365/230.03

(57) ABSTRACT

A method and circuit is disclosed for refreshing a memory system. The memory system has a first memory block coupled to a refresh timer, and one or more subsequent memory blocks without refresh timers contained therein. The refresh timer generates a system refresh signal for refreshing the memory system, and all memory blocks have a refresh controller contained therein which enable sequential refresh of the subsequent memory blocks.

### BACKGROUND

The present disclosure relates generally to semiconductor devices, and more particularly to semiconductor memory devices. Still more particularly, the present disclosure relates to a ripple refresh circuit and a method for using such a ripple refresh circuit to sequentially refresh individual memory blocks for decreasing the required memory device instantaneous power consumption.

In dynamic random access memories (DRAMs), it is necessary for the information stored in the memory cells to be periodically refreshed, since the memory cells can retain the information stored in them for only a limited time. The reason for this is that capacitors are used as memory cells for DRAMs. These capacitors discharge themselves after a specific time as a result of unavoidable internal quiescent currents, so that the stored charges of the capacitors have to be regularly renewed. The period of time in which the memory cells hold their stored charge is known as its data retention time. The memory cells are therefore recharged at fixed predetermined time intervals, so-called refresh cycles. The pulse for recharging, the so-called refresh pulse, can be generated internally within the module or else externally. In modern DRAMs, refresh cycles of at least 4096 refresh operations per 64 ms (refresh rate 6 k/64 ms) are customary.

The refresh cycle for the DRAM, i.e. the interval between the individual refresh pulses, must be chosen such that even the memory cell with the shortest retention time, which specifies how long the memory content can be retained in the associated cell, is refreshed again in good time.

The conventional refresh method for DRAMs perform simultaneous refresh operations on all memory blocks of the DRAM. This results in a high peak instantaneous current spike within the DRAM device. The current spike generates additional internal noise that can affect circuit operation and cause larger supply voltage fluctuations. In addition, the supply voltage power regulators must be designed to handle this peak current requirement which results in a less efficient design and potential additional space requirements.

Desirable in the art of semiconductor memory design are improved memory refresh methods and circuits with which better control of the instantaneous power consumption can be reduced.

### SUMMARY

In view of the foregoing, this disclosure provides a circuit and method to improve memory performance, stability, and power consumption.

In one example, this circuit and method comprises a modified memory system that incorporate the sequential or ripple refresh capability. The memory system has a first memory block coupled to a refresh timer, and one or more subsequent memory blocks without refresh timers contained therein. The refresh timer generates a system refresh signal for refreshing the memory system, and all memory blocks have refresh controllers contained therein which enable sequential refresh of the subsequent memory blocks.

The improved memory system has a much lower peak instantaneous current, reduced supply voltage fluctuations, and lower internal noise generation, resulting in a more stable circuit operation. It also reduces supply voltage regulator peak current requirements, and reduces DC supply voltage currents due to the elimination of redundant refresh timer circuitry located in each memory block.

Various aspects and advantages will become apparent from the following detailed description, taken in conjunction with the accompanying drawings, illustrating the principles of the disclosure by way of examples.

### BRIEF DESCRIPTION OF THE DRAWINGS

FIG. 1 illustrates a conventional DRAM memory system.

FIG. 2 illustrates a memory block in the conventional DRAM memory system.

FIG. 3 illustrates a timing diagram of a refresh operation in the conventional DRAM memory system.

FIG. 4 illustrates a ripple refresh DRAM memory system in accordance with one example of the present disclosure.

FIG. 5A illustrates a memory block of the ripple refresh DRAM memory system in accordance with one example of the present disclosure.

FIG. 5B illustrates a refresh memory block of the ripple refresh DRAM memory system in accordance with one example of the present disclosure.

FIG. 6 illustrates a timing diagram of a ripple refresh operation in the ripple refresh DRAM memory system in accordance with one example of the present disclosure.

### DESCRIPTION

The present disclosure provides a method and circuit for controlling memory refresh operations of memory blocks in a semiconductor device. In the present disclosure, a ripple refresh circuit for each memory block is used for reduction of the memory device instantaneous power consumption.

Although the invention is illustrated and described herein as embodied in a circuit and method for refreshing memory cells in a DRAM device below, it is nevertheless not intended to be limited to the details shown, since various modifications and structural changes may be made to various memory devices.

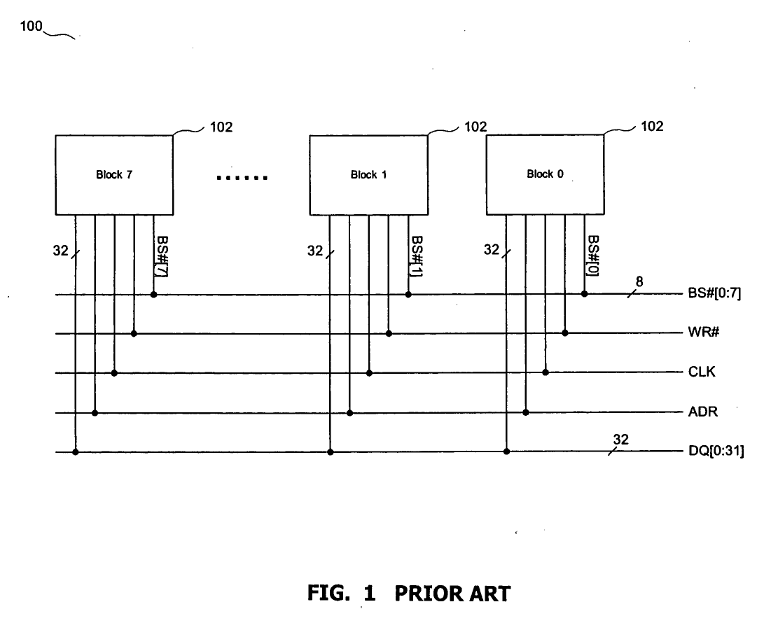

FIG. 1 illustrates a conventional DRAM memory system 100. In this example, the memory system 100 has eight memory blocks 102 (Blocks 0 to 7). All eight memory blocks 102 in the memory system 100 are identical. Each memory block 102 receives a block select signal BS# from the DRAM control logic that activates the selected memory block. The write-read signal WR# is sent to each of the memory blocks 102 to enable the read or write function of those memory blocks. The system clock CLK is sent to each of the memory blocks 102 to provide the proper timing of the memory blocks required by the memory system 100. Multiple address lines ADR are supplied to each of the memory blocks 102 that will allow read or write functions from the selected cell locations. There are 32 data lines DQ that allow for the data to be read to or written from the memory blocks 102. In the memory system 100, all 8 blocks are refreshed simultaneously, thereby generating a high peak instantaneous current spike on the system voltage supply lines.

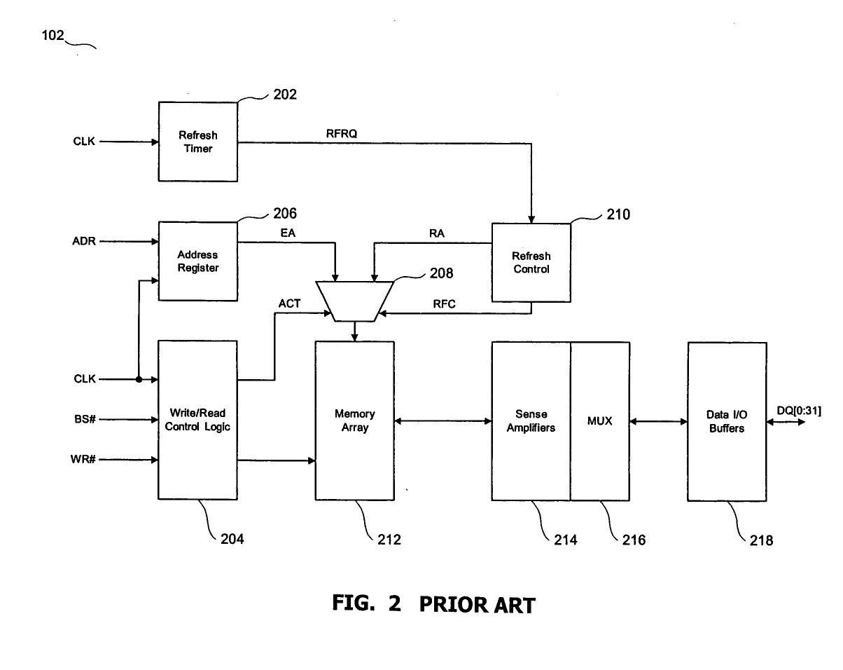

FIG. 2 illustrates a memory block 102 of the memory system 100. In this diagram, a clock signal CLK is input to the refresh timer 202, a write/read control logic module 204, and an address register module 206 to provide address register synchronization with the refresh and read/write operations of the memory system 100. The block select BS# and write/read signals WR# are fed into the write/read control logic module 204 for memory block selection and write/read operation, respectively. For the read/write operation, the address lines ADR are input to the address register module 206 for selection of the cells in the memory blocks in which a read or write is to be performed. The address register module 206 provides the read/write address EA to one input of the multiplexer switch 208. The other input of the multiplexer switch 208 receives the refresh address RA for the refresh sequence. The output of the multiplexer switch 208 is controlled by the control signals ACT and RFC. The ACT signal is generated during a read/write operation of the memory blocks as controlled by the write/read control logic module 204. The refresh control signal RFC is generated by the refresh control circuit 210 based on the refresh request signal RFRQ, which initiates the refresh cycle for the memory system 100.

The refresh timer 202 generates a periodic refresh request signal RFRQ at the appropriate time for the refresh operation as needed by the memory system 100. This refresh request RFRQ signal is routed to the refresh control circuit 210 and generates the refresh command RFC as well as the refresh address lines RA to control the sequence of the refresh operation. The RFC signal is generated only during the refresh operation, which in turn is controlled by the refresh control circuit 210 and the RFRQ signal. During a refresh operation, the multiplexer switch 208 supplies RA address lines to the memory array 212. During the read/write operation, the multiplexer switch 208 supplies the EA address lines to the memory array 212.

When the memory array 212 cells are selected for a read function, the data will be sent from the memory array 212 to the sense amplifiers 214, through a multiplexer switch 216, through the data I/O buffers 218 and external to the memory system 100 for further processing by external circuitry. When a write function is selected, the input data is received by the data I/O buffers 218, sent to the multiplexer 216, through the sense amplifiers 214, and written into the selected cells of the memory array 212.

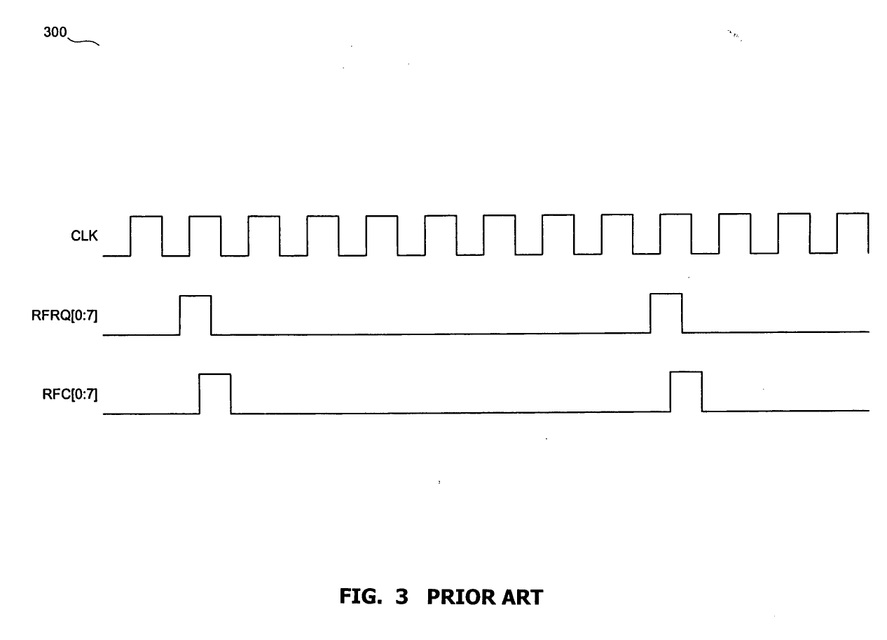

FIG. 3 illustrates a timing diagram 300 of a refresh operation of the memory system 100. With reference to FIGS. 2 and 3, the system clock CLK is sent to the refresh timer 202, which generates a refresh request signal RFRQ at the appropriate time for the initiation of the refresh operation. This RFRQ signal is sent to the refresh control circuit 210, which in turn generates a refresh control signal RFC as shown in the FIG. 3 timing diagram. In this example, all 8 memory blocks are refreshed simultaneously resulting in a high peak instantaneous current spike on the voltage supply lines of the memory system. After 8 clock cycles, the refresh cycle starts once again by the refresh timer 202, which generates the RFRQ signal, which is, in turn, feed into the refresh control circuit 210 to generate the RFC signal.

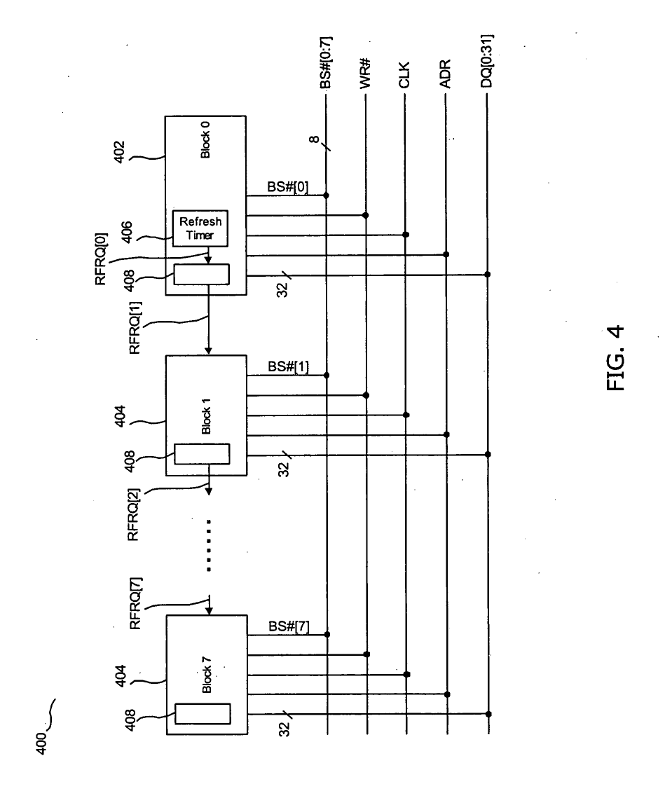

FIG. 4 illustrates a ripple refresh DRAM memory system 400 in accordance with one example of the present disclosure. In this example, the memory system 400 includes a refresh memory block 402 (Block 0) and 7 other memory blocks 404 (Blocks 1 to 7). It is, however, understood by those skilled in the art that the number of blocks within the memory system is scalable and may be changed without deviation to the intention of this disclosure. The refresh memory block 402 actually is also structurally similar to other memory blocks except that it is the first one to be refreshed. Refresh memory block 402 includes a refresh timer 406 and a refresh control circuit 408 that generate the refresh request signals RFRQ[0] and RFRQ[1], respectively, thereby initiating the refresh sequence for the memory system 400 by starting to refresh the first memory block and making the next memory block (Block 1) ready for refresh. After RFRQ[0] is generated for itself, which triggers the refresh process for the refresh memory block, request signals RFRQ[1] is generated for Block 1. Similarly, RFRQ[0] is not generated until Block 7 is refreshed. A Block N of memory blocks 404 includes a refresh control circuit 408 that generates the refresh request signal RFRQ[N+1] for the next memory block, where N+1 is the next memory block. For example, the refresh control circuit 408 of Block 1 generates a refresh signal RFRQ[2], which is fed into Block 2.

In short, Block 0 initiates the refresh operation for the memory system 400 and generates the refresh request signal RFRQ[1] for Block 1, thereby initiating the refresh sequence for Block 1 on the next clock cycle. Block 1, in turn, generates the refresh request RFRQ[2] for the next memory block, or Block 2, thereby initiating the refresh sequence for Block 2 on the next clock cycle. This refresh operation repeats until Block 7 is refreshed and the cycle starts over again at Block 0, through the refresh timer 406 of Block 0. The sequential refreshing of the memory Blocks 0 through 7 results in a ripple effect of the refresh operation. Since only one memory block is refreshed at a time, the peak instantaneous current is significantly reduced.

Each of Blocks 0 to 7 receives a block select signal BS# from the DRAM control logic that activates the selected memory block. The write-read signal WR# is also sent to each of the Blocks 0 to 7, thereby enabling the read or write function of those memory blocks. The system clock CLK is sent to each of the Blocks 0 to 7 to provide the proper timing of the memory blocks required by the memory system 400. Multiple address lines ADR are supplied to each of the Blocks 0 to 7 that will allow read or write functions from the selected cell locations. There are 32 data lines DQ that allow for the data to be read to or written from the memory Blocks 0 to 7.

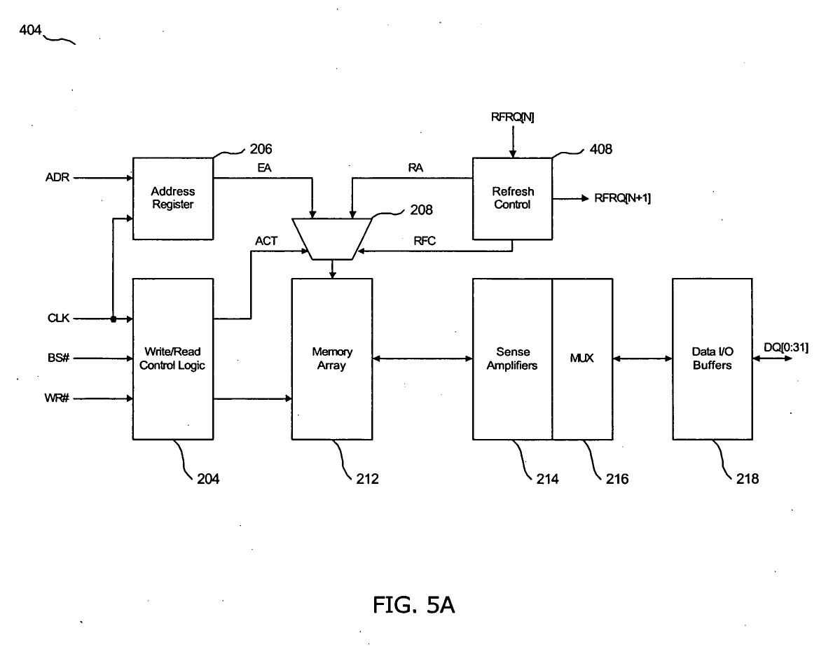

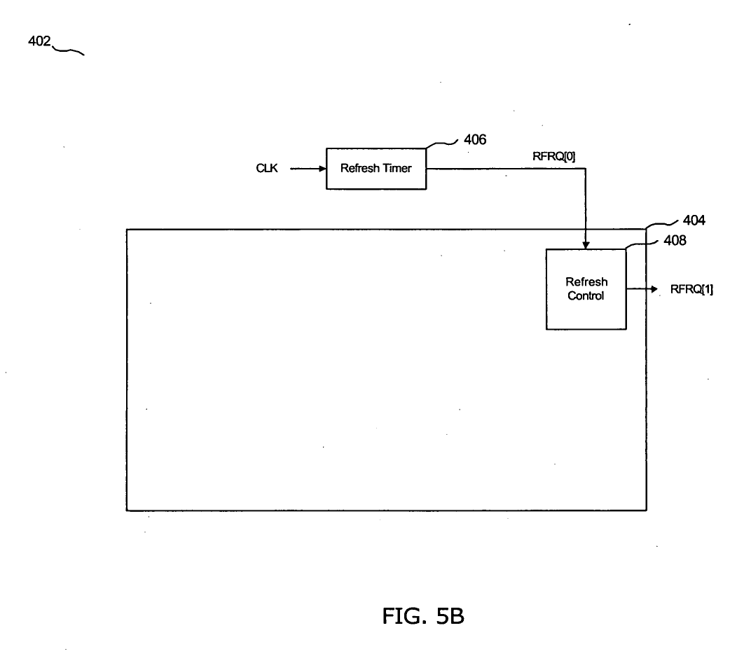

FIG. 5A illustrates the internal circuitry of the memory block 404 of the memory system 400 in accordance with one example of the present disclosure. With reference to FIGS. 2 and 5A, the memory block 404 is similar to the memory block 102 except that the refresh control circuit 210 is deleted while the refresh control circuit 408 is added. The circuit modules 204, 206, 208, 212, 214, 216 and 218 operate identically as explained in FIG. 2.

In this example, the refresh control circuit 408 of Block N receives the refresh request signal RFRQ[N] from the previous memory block, or Block N−1, thereby starting Block N's refresh sequence. Block N also generates the refresh request signal RFRQ[N+1] for the next memory block, or Block N+1. As an example, Block 1 receives the signal RFRQ[1] from Block 0 and sends the signal RFRQ[2] to Block 2. As another example, Block 4 receives the signal RFRQ[4] from Block 3 and sends the signal RFRQ[5] to Block 5.

FIG. 5B illustrates the internal circuitry of the refresh memory block 402 in accordance with one example of the present disclosure. With reference to FIGS. 5A and 5B, the refresh memory block 402 differs from the memory block 404 by the addition of the refresh timer 406. Instead of receiving the refresh request signal RFRQ[N] from a memory block, the refresh memory block 402 receives the first refresh request signal RFRQ[0] from the refresh timer 406, which is controlled by a system clock signal “CLK.” The RFRQ[0] can be viewed as a system refresh signal since the refresh timer 406 generates it based largely on the length of the retention cycle of the memory system. The retention cycle is the time period the memory device can hold the information without refreshing. The timing for generating the system refresh signal has to assure that all memory blocks controlled by corresponding ripple refresh control circuits will have their refresh operations done in each retention cycle. In this example, and with reference to FIGS. 4 and 5B, the refresh control circuit 408 initiates the refresh process for the memory system 400 and generates the refresh request signals RFRQ[0] and RFRQ[1].

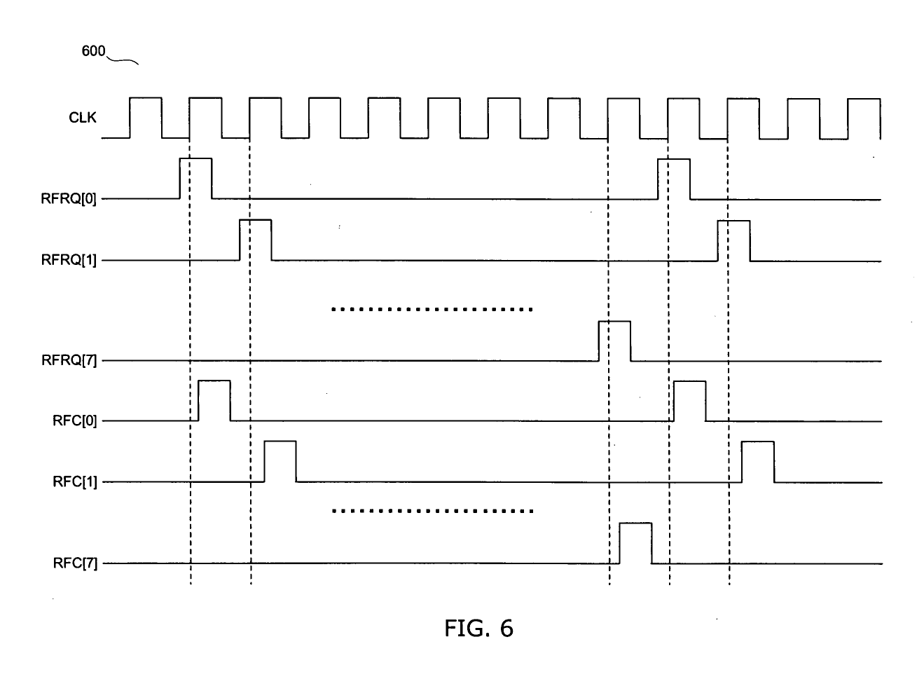

FIG. 6 illustrates a timing diagram 600 of a ripple refresh operation in the ripple refresh DRAM memory system 400 in accordance with one example of the present disclosure. The system clock CLK is sent to the refresh timer 406 in the refresh memory block 402, which generates a refresh request signal RFRQ[0]. This signal is applied to the refresh control circuit 408 of the refresh memory block 402, thereby generating the refresh control signal RFC[0] for the initiation of the refresh operation in the refresh memory block 402, or Block 0. One clock cycle later, the refresh request signal RFRQ[1] is generated and sent to the refresh control circuit 408 of Block 1, which generates the refresh command RFC[1] that initiates refresh cycle of Block 1. One clock cycle later, the refresh control circuit 408 of Block 1 generates a refresh request signal RFRQ[2] that is sent to the refresh control circuit 408 of Block 2, which then generates the refresh command signal RFC[2]. This sequence continues through Block 7 and is then restarted at and by Block 0. In this example, the refresh cycle repeats every 8 clock cycles as seen graphically in FIG. 6.

It is noticed that in FIG. 6, RFRQ signals for various memory blocks are not overlapping in timing so that at any moment, there is only one memory block that receives a refresh command RFC. The purpose of arranging the signal generation in such a manner is to achieve the lowest instantaneous power consumption during the memory refresh operations. However, in some instances, this most desired approach may not be practical, and certain memory blocks may receive their refresh command in about the same time or have some overlaps in timing. This arrangement is still better than having all memory blocks enter memory refresh operations simultaneously.

The advantages of this ripple refresh memory system include much lower peak instantaneous current, reduced supply voltage fluctuations and, lower internal noise generation, resulting in a more stable circuit operation, reduced supply voltage regulator peak current requirements and, reduced DC supply voltage currents due to elimination of redundant refresh timer circuitry located in the memory blocks. In addition, the memory block layout areas are also reduced due to the elimination of the refresh timer in all but one of the memory blocks.

The above disclosure provides many different embodiments or examples for implementing different features of the disclosure. Specific examples of components and processes are described to help clarify the disclosure. These are, of course, merely examples and are not intended to limit the disclosure from that described in the claims.

Although illustrative embodiments of the disclosure have been shown and described, other modifications, changes, and substitutions are intended in the foregoing disclosure. Accordingly, it is appropriate that the appended claims be construed broadly and in a manner consistent with the scope of the disclosure, as set forth in the following claims.

1. A method for refreshing a memory system having a predetermined number of memory blocks, comprising:
providing a system refresh signal for refreshing the memory system, the system refresh signal being used as a first refresh request signal for refreshing a first memory block;
sequentially refreshing one or more subsequent memory blocks of the memory system such that no two memory blocks are refreshed at the same time,
wherein all the memory blocks are refreshed within a retention cycle of the memory system.

2. The method of claim 1 wherein the providing further includes generating the system refresh signal by a refresh timer coupled to the first memory block.

3. The method of claim 1 wherein the sequentially refreshing further includes sequentially generating one or more refresh request signals for the subsequent memory blocks.

4. The method of claim 3 wherein the sequentially refreshing further includes providing a refresh request signal by a refresh control circuit in each subsequent memory block to its immediately subsequent memory block while it is undergoing a refresh operation.

5. The method of claim 4 wherein the sequentially refreshing further includes generating a refresh command based on the refresh request signal for refreshing each memory block.

6. The method of claim 4 wherein the refresh commands for the memory blocks do not overlap in timing.

7. The method of claim 3 wherein the refresh requests do not overlap in timing.

8. A memory system comprising:
a first memory block coupled to a refresh timer; and
one or more subsequent memory blocks without refresh timers contained therein,
wherein the refresh timer generates a system refresh signal for refreshing the memory system, and
wherein all memory blocks have a refresh controller contained therein which enable sequential refresh of the subsequent memory blocks, such that no two memory blocks are refreshed at the same time.

9. The memory system of claim 8 wherein the refresh controller of the first memory block receives the system refresh signal generated by the refresh timer.

10. The memory system of claim 8 wherein the refresh controller of each memory block generates a refresh request for an immediately subsequent memory block.

11. The memory system of claim 10 wherein the refresh controller of each memory block generates a refresh request for an immediately subsequent memory block when the memory block it belongs to is being refreshed.

12. The memory system of claim 10 wherein the refresh requests generated do not overlap in timing.

13. The memory system of claim 10 wherein the refresh controller of each memory block generates a refresh command for refreshing the memory block it belongs to.

14. The memory system of claim 13 wherein the refresh commands generated do not overlap in timing.

15. The memory system of claim 8 wherein the refresh controller provides a refresh address.

16. A dynamic random access memory system comprising:
a first memory block coupled to a refresh timer; and
one or more subsequent memory blocks without refresh timers contained therein,
wherein the refresh timer generates a system refresh signal for refreshing the memory system, and
wherein all memory blocks have a refresh controller contained therein which enable sequential refresh of the subsequent memory blocks, such that no two memory blocks are refreshed at the same time.

17. The memory system of claim 16 wherein the refresh controller of the first memory block receives the system refresh signal generated by the refresh timer.

18. The memory system of claim 16 wherein the refresh controller of each memory block generates a refresh command for refreshing the memory block it belongs to and a refresh request for an immediately subsequent memory block when the memory block it belongs to is being refreshed.

19. The memory system of claim 18 wherein the refresh requests generated do not overlap in timing.

20. The memory system of claim 18 wherein the refresh commands generated do not overlap in timing.

21. The memory system of claim 16 wherein the refresh controller provides a refresh address.
